(19) United States
(12) Patent Application Publication
(10) Pub. No.: US 2006/0145336 A1
(43) Pub. Date: Jul. 6, 2006

(54) Heat sink

(75) Inventor: Yen-Hsun Chou, Taoyuan city (TW)

Correspondence Address: BROWDY AND NEIMARK, P.L.L.C.;624 NINTH STREET, NW, SUITE 300, WASHINGTON, DC, 20001-5303, US

(73) Assignee: Yuh-Cheng Chemical Ltd., Taipei City (TW)

(21) Appl. No.: 11/025,947

(22) Filed: Jan. 3, 2005

(51) Int. Cl. H01L 23/34

(52) U.S. Cl. 257/722; 257/712

(57) ABSTRACT

A heat sink is formed of a plurality of plate members stacked together. Each plate member includes a body, a first sidewall extending from a lateral side of the body, a second sidewall extending from another lateral side of the body, two retaining members which are provided at the first sidewall and have respectively a recessed portion at an inner side thereof and a hooked portion at an outer side thereof, and two mounting through holes formed in the body for insertion of the retaining members of another plate member such that the plate members can be firmly rapidly assembled together.

### BACKGROUND OF THE INVENTION

1. Field of the Invention

The present invention relates to a heat sink for dissipating heat from a heat source and more particularly, to such a heat sink, which has a tight structure and is easy to install.

2. Description of the Related Art

FIG. 6 shows a heat sink according to the prior art. According to this design, the heat sink 1 is formed of a plurality of metal plate members 2 connected in a stack. Each metal plate member 2 has a plurality of mounting lugs 3 and a plurality of mounting through holes 4 corresponding to the mounting lugs 3. Each mounting lug 3 has a base 5 and two upright arms 6 at two sides of the base 5. During installation, the metal plate members 2 are fastened together by inserting the mounting lugs 3 of one metal plate member 2 into the mounting through holes 4 of another metal plate member 2 and then hammering down the upright arms 6 of each mounting lug 3. This structure of heat sink 1 is strong, however its complicated installation process requires much time and labor, resulting in a high manufacturing cost.

FIG. 7 shows another structure of heat sink 7 according to the prior art. According to this design, the heat sink 7 is comprised of a plurality of metal plat members 8 connected in a stack. Each metal plate member 8 comprises a plurality of retaining lugs 9 and a plurality of mounting through holes 92. Each retaining lug 9 has a crevice 91 that makes the respective retaining lug 9 compressible. By means of forcing the retaining lugs 9 of one metal plate member 8 into the mounting through holes 92 of another, the metal plate members 8 are fastened together. This structure of heat sink is not strong because the retaining lugs 9 of one metal plate members 8 tend to be pulled away from the mounting through holes 92 of another metal plate member 8 accidentally.

### SUMMARY OF THE INVENTION

The present invention has been accomplished under the circumstances in view. It is one objective of the present invention to provide a heat sink, which has a tight structure and is easy to install.

To achieve this objective of the present invention, the heat sink provided by the present invention is formed of a plurality of plate members stacked together. Each the plate member comprises a body, a first sidewall extending from a lateral side of the body, a second sidewall extending from another lateral side of the body, two retaining members which are provided at the first sidewall and have respectively a recessed portion at an inner side thereof and a hooked portion at an outer side thereof, and two mounting through holes formed in the body for insertion of the retaining members of another plate member such that the plate members can be firmly rapidly assembled together.

### BRIEF DESCRIPTION OF THE DRAWINGS

FIG. 1 is an exploded view of a heat sink according to the present invention.

FIG. 2 is a sectional view in an enlarged scale of one metal plate member according to the present invention.

FIG. 3 is a sectional view in an enlarged scale of a part of the present invention, showing two metal plate members fastened together.

FIG. 4 is a schematic side plain view showing the relative locations of the retaining members and the mounting through holes.

FIG. 5 is a schematic drawing showing the connection action between two metal plate members.

FIG. 6 is a perspective view of a part of a heat sink according to the prior art.

FIG. 7 is a sectional view showing another structure of heat sink according to the prior art.

### DETAILED DESCRIPTION OF THE INVENTION

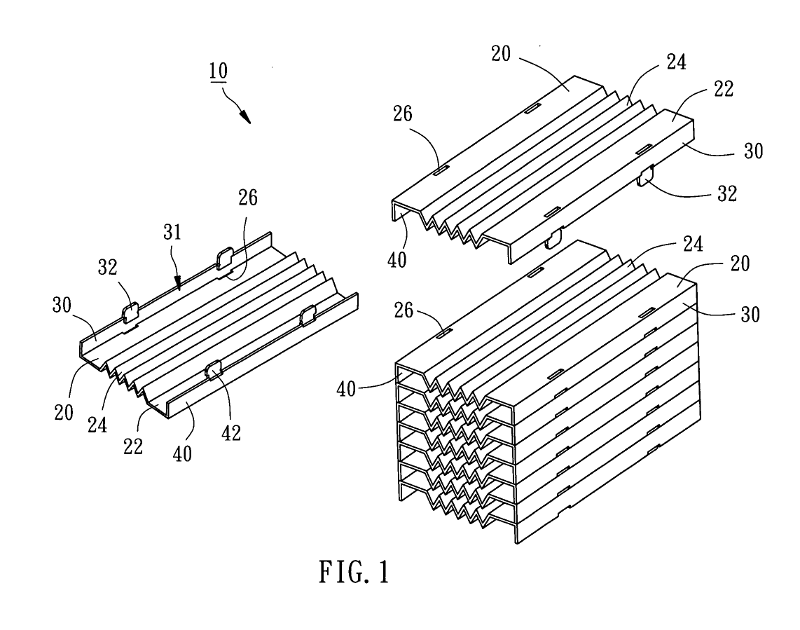

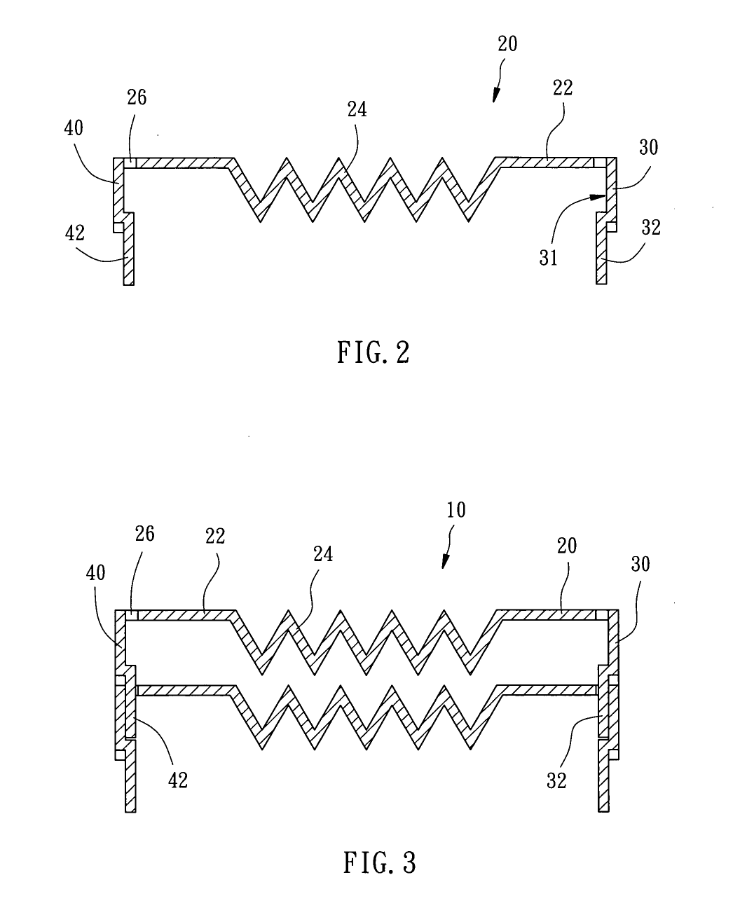

Referring to FIGS. 1 and 2, a heat sink 10 in accordance with the present invention is shown comprised of a plurality of metal plate members 20 connected in a stack. Each metal plate member 20 comprises a body 22, a first sidewall 30 perpendicularly extending from one lateral side of the body 22, and a second sidewall 40 perpendicularly extending from the other lateral side of the body 22. The metal plate members 30 are made of heat conducting material, for example, copper or aluminum.

The first sidewall 30 has two retaining members 32 respectively downwardly extending from the inner side 31 of the first sidewall. The retaining members 32 each have a recessed portion 34 at the respective inner side and a hooked portion 36 at the respective outer side.

The second sidewall 40 has two retaining members 42 corresponding to the retaining members 32 of the first sidewall 30.

The body 22 has a corrugated portion 24 on the middle to extend the heat dissipation area, two symmetrical pairs of mounting through holes 26 respectively disposed adjacent to the first sidewalls 30 and the second sidewalls 40.

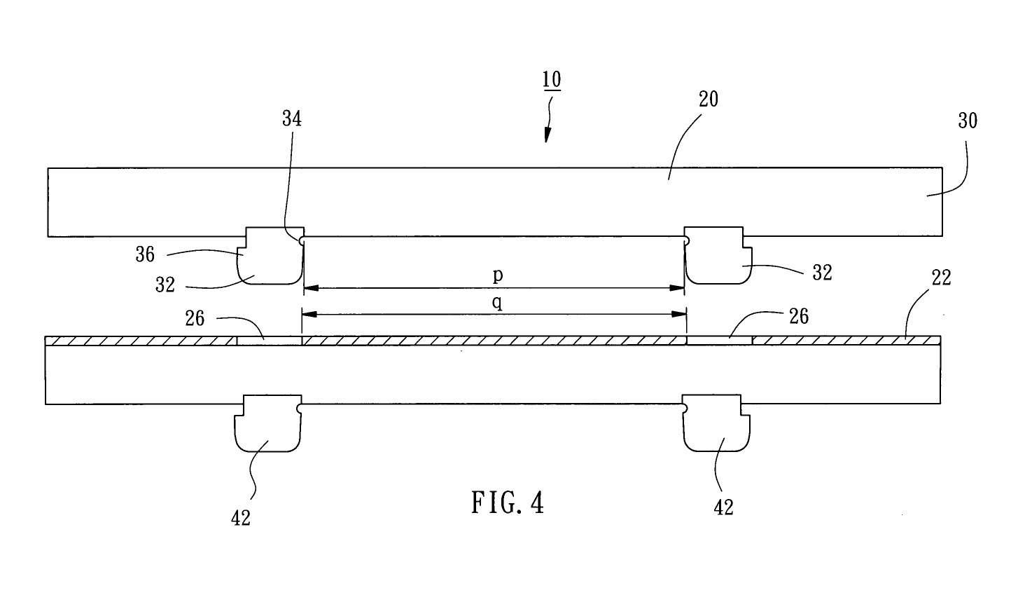

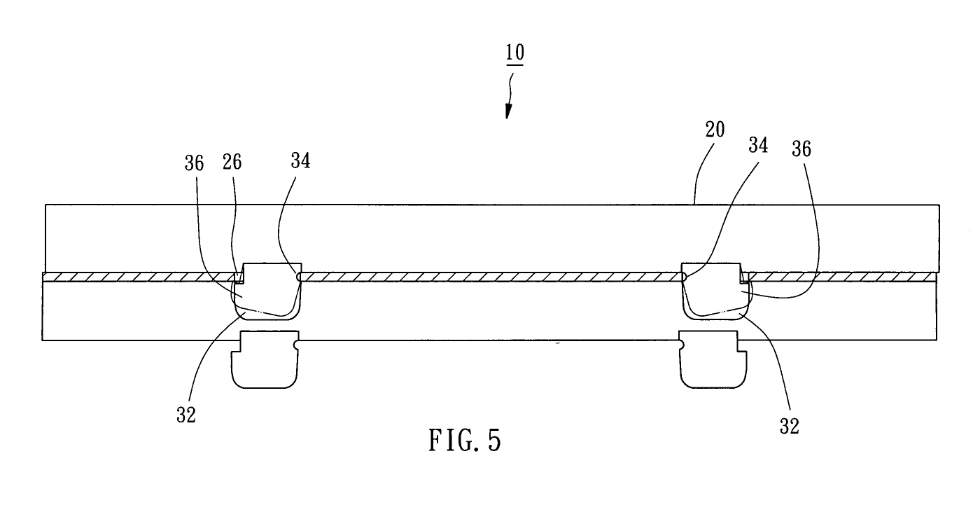

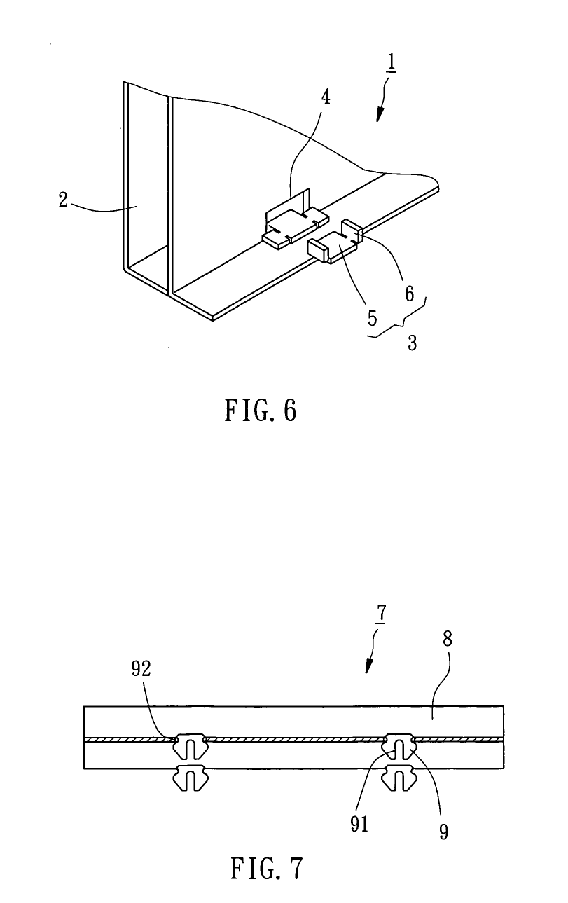

Referring to FIGS. 3-5, the distance p between the two retaining members 32 or 42 is slightly smaller than the distance q between the two adjacent mounting through holes 36. When inserting the retaining members 32 and 42 of one metal plate member 20 into the mounting through holes 26 of another metal plate member 20 with force, the retaining members 32 and 42 are slightly deformed (see the imaginary line in FIG. 5). After insertion, the recessed portions 34 of the retaining members 32 and 42 of the first metal plate member 20 are maintained closely attached to the peripheral edge of the mounting through holes 26 of the second metal plate member 20, and the hooked portions 36 of the retaining members 32 and 42 of the first metal plate member 20 are maintained hooked on the bottom edge of the body of the second metal plate member 20. By means of this mounting procedure, the metal plate members 20 are fastened together in a stack and will not be separated from one another when stretched.

As indicated above, the heat sink can easily be assembled simply by inserting the retaining members 32 and 42 of one metal plate member 20 into the mounting through holes 26 of another metal plate member 20. When assembled, the whole structure is maintained tight.

Although a particular embodiment of the invention has been described in detail for purposes of illustration, various modifications and enhancements may be made without departing from the spirit and scope of the invention. For example, the first sidewall and the second sidewall may be respectively perpendicularly extending from two adjacent sides of the body. Accordingly, the invention is not to be limited except as by the appended claims

What is claimed is:

1. A heat sink comprising a plurality of plate members assembled together, each said plate member comprising a body, a first sidewall extending from a lateral side of the body, a second sidewall extending from another lateral side of the body, two retaining members which are provided at the first sidewall and have respectively a recessed portion at an inner side thereof and a hooked portion at an outer side thereof, and two mounting through holes formed in the body for insertion of the retaining members of another said plate member

2. The heat sink as claimed in claim 1, wherein the distance between the two retaining members of said plate member is shorter than the distance between the two mounting through holes of said plate member.

3. The heat sink as claimed in claim 1, wherein the recessed portion of the retaining member of one of said plate members is forced into engagement with a periphery edge of the corresponding mounting through hole of another said plate member.

4. The heat sink as claimed in claim 1, wherein the hooked portion of the retaining member of one of said plate members is hooked on the body of another said plate member.

5. The heat sink as claimed in claim 1, wherein said body has a corrugated portion.
